(19) United States
(12) Patent Application Publication
(10) Pub. No.: US 2026/0092985 A1
(43) Pub. Date: Apr. 2, 2026

(54) SECONDARY BATTERY STATE ESTIMATION SYSTEM, SECONDARY BATTERY STATE ESTIMATION METHOD, AND PROGRAM

(71) Applicant: HONDA MOTOR CO., LTD., Tokyo (JP)

(72) Inventors: Takuma Kawahara, Wako-shi (JP); Yuki Sato, Utsunomiya-shi (JP); Koji Sato, Utsunomiya-shi (JP)

(21) Appl. No.: 19/324,168

(22) Filed: Sep. 10, 2025

(30) Foreign Application Priority Data
Sep. 30, 2024 (JP) 2024-171827

(51) Int. Cl. G01R 31/392; G01R 31/3835

(52) U.S. Cl. CPC G01R 31/392; G01R 31/3835

(57) ABSTRACT

A system including a secondary battery state estimation device includes an optimization portion that estimates the degradation degree of a secondary battery to be estimated. The optimization portion acquires a plurality of parameters relating to a state of the secondary battery to be estimated based on voltage data which is acquired in the secondary battery to be estimated. The optimization portion differentiates a search range when acquiring a predetermined parameter among the plurality of parameters at a first time and a search range when acquiring the predetermined parameter at a second time that is different from the first time.

### CROSS-REFERENCE TO RELATED APPLICATION

Priority is claimed on Japanese Patent Application No. 2024-171827, filed on Sep. 30, 2024, the contents of which are incorporated herein by reference.

### BACKGROUND

### Field of the Invention

The present invention relates to a secondary battery state estimation system, a secondary battery state estimation method, and a program.

### Background

In recent years, in order to ensure that more people have access to affordable, reliable, sustainable, and advanced energy, research and development relating to a secondary battery which contributes to energy efficiency has been conducted.

In the related art, for example, a device is known which acquires an OCV (Open Circuit Voltage) curve indicating a change in the open circuit voltage (OCV) in accordance with a discharge capacity based on history data of the voltage and the current of a battery and an OCP (Open Circuit Potential) curve indicating a change in an open circuit potential (OCP) in accordance with a discharge capacity of each of a positive electrode and a negative electrode (for example, refer to PCT International Publication No. WO 2023/054443 and Japanese Unexamined Patent Application, First Publication No. 2003-48545).

### SUMMARY

In a technique relating to a secondary battery, it is a problem to prevent a decrease in an estimation accuracy of an internal state including an OCV curve or the like, for example, even when the number of parameters of the internal state to be diagnosed increases. For example, in each device of the related art described above, when a uniform diagnosis process is performed on each of a plurality of parameters of the internal state to be diagnosed, there is a possibility that variation (uncertainty) of a diagnosis result increases in association with an increase in the number of parameters.

An aspect of the present invention aims at achieving prevention of a decrease in an estimation accuracy of an internal state even when the number of parameters of the internal state of a secondary battery to be diagnosed increases.

A secondary battery state estimation system according to a first aspect of the present invention includes: a degradation estimation portion that acquires a plurality of parameters relating to a state of a secondary battery to be estimated based on voltage data which is acquired in the secondary battery to be estimated or which is acquired by data acquired in a secondary battery and thereby estimates the degradation degree of the secondary battery to be estimated, wherein the degradation estimation portion differentiates a search range when acquiring a predetermined parameter among the plurality of parameters at a first time and a search range when acquiring the predetermined parameter at a second time that is different from the first time.

A second aspect is the secondary battery state estimation system according to the first aspect described above, wherein the degradation estimation portion may differentiate a search range when acquiring a first parameter which is the predetermined parameter among the plurality of parameters at a predetermined time and a search range when acquiring a second parameter that is different from the first parameter among the plurality of parameters at the predetermined time.

A third aspect is the secondary battery state estimation system according to the second aspect described above, wherein the degradation estimation portion may set a search range when acquiring the first parameter at the first time to be larger than a search range when acquiring the second parameter at the first time and may set a search range when acquiring the first parameter at the second time to be smaller than a search range when acquiring the second parameter at the second time.

A fourth aspect is the secondary battery state estimation system according to the first aspect described above, wherein the degradation estimation portion may set a first group and a second group which have a search range different from each other and in each of which at least one parameter is classified from the plurality of parameters and may change classification in which the plurality of parameters are classified into the first group and the second group at each different time.

A fifth aspect is the secondary battery state estimation system according to the first aspect described above, wherein the degradation estimation portion may classify the plurality of parameters into a first group having at least one parameter and a second group having at least one parameter and may differentiate a search range when acquiring a parameter of the first group at a predetermined time and a search range when acquiring a parameter of the second group at the predetermined time.

A sixth aspect is the secondary battery state estimation system according to the fifth aspect described above, wherein the degradation estimation portion may set a search range when acquiring a parameter of the first group at the first time to be larger than a search range when acquiring a parameter of the second group at the first time and may set a search range when acquiring a parameter of the first group at the second time to be smaller than a search range when acquiring a parameter of the second group at the second time.

A secondary battery state estimation system according to a seventh aspect of the present invention includes: a degradation estimation portion that acquires a plurality of parameters relating to a state of a secondary battery to be estimated based on voltage data which is acquired in the secondary battery to be estimated or which is acquired by data acquired in a secondary battery and thereby estimates the degradation degree of the secondary battery to be estimated, wherein the degradation estimation portion differentiates a search range when acquiring a first parameter among the plurality of parameters at a predetermined time and a search range when acquiring a second parameter that is different from the first parameter among the plurality of parameters at the predetermined time.

A secondary battery state estimation method according to an eighth aspect of the present invention is a method performed by an electronic apparatus including a process portion that estimates the degradation degree of a secondary battery to be estimated, the method including: acquiring a plurality of parameters relating to a state of the secondary battery to be estimated based on voltage data which is acquired in the secondary battery to be estimated or which is acquired by data acquired in a secondary battery; and differentiating a search range when acquiring a predetermined parameter among the plurality of parameters at a first time and a search range when acquiring the predetermined parameter at a second time that is different from the first time.

A secondary battery state estimation method according to a ninth aspect of the present invention is a method performed by an electronic apparatus including a process portion that estimates the degradation degree of a secondary battery to be estimated, the method including: acquiring a plurality of parameters relating to a state of the secondary battery to be estimated based on voltage data which is acquired in the secondary battery to be estimated or which is acquired by data acquired in a secondary battery; and differentiating a search range when acquiring a first parameter among the plurality of parameters at a predetermined time and a search range when acquiring a second parameter that is different from the first parameter among the plurality of parameters at the predetermined time.

A tenth aspect of the present invention is a computer-readable non-transitory recording medium that records a program causing a computer of an electronic apparatus including a process portion that estimates the degradation degree of a secondary battery to be estimated to execute: acquiring a plurality of parameters relating to a state of the secondary battery to be estimated based on voltage data which is acquired in the secondary battery to be estimated or which is acquired by data acquired in a secondary battery; and differentiating a search range when acquiring a predetermined parameter among the plurality of parameters at a first time and a search range when acquiring the predetermined parameter at a second time that is different from the first time.

An eleventh aspect of the present invention is a computer-readable non-transitory recording medium that records a program causing a computer of an electronic apparatus including a process portion that estimates the degradation degree of a secondary battery to be estimated to execute: acquiring a plurality of parameters relating to a state of the secondary battery to be estimated based on voltage data which is acquired in the secondary battery to be estimated or which is acquired by data acquired in a secondary battery; and differentiating a search range when acquiring a first parameter among the plurality of parameters at a predetermined time and a search range when acquiring a second parameter that is different from the first parameter among the plurality of parameters at the predetermined time.

According to the first aspect described above, by including the degradation estimation portion that changes the search range at each different timing when acquiring the predetermined parameter, even when the number of parameters of an internal state of the secondary battery to be diagnosed increases, it is possible to prevent a decrease in an estimation accuracy of the internal state. For example, compared to the case where the search range is not changed, it is possible to prevent an increase in variation (uncertainty) of an estimation result in association with an increase in the number of parameters.

In the case of the second aspect described above, by including the degradation estimation portion that changes the search ranges of the different parameters at the same timing, even when the number of parameters of the internal state of the secondary battery to be diagnosed increases, it is possible to prevent the decrease in the estimation accuracy of the internal state. For example, compared to the case where the search ranges of the different parameters are not changed, it is possible to prevent the increase in variation (uncertainty) of the estimation result in association with the increase in the number of parameters.

In the case of the third aspect described above, by including the degradation estimation portion that changes sizes of the search ranges of the different parameters at each different timing, even when the number of parameters increases, it is possible to prevent the decrease in the estimation accuracy of the internal state.

In the case of the fourth aspect described above, by including the degradation estimation portion that changes the classification of the plurality of parameters with respect to the groups in which a different search range is set at each different timing, even when the number of parameters increases, it is possible to prevent the decrease in the estimation accuracy of the internal state.

In the case of the fifth aspect described above, by including the degradation estimation portion that changes the search ranges of the parameters of the different groups at the same timing, even when the number of parameters increases, it is possible to prevent the decrease in the estimation accuracy of the internal state.

In the case of the sixth aspect described above, by including the degradation estimation portion that changes sizes of the search ranges of the parameters of the different groups at each different timing, even when the number of parameters increases, it is possible to prevent the decrease in the estimation accuracy of the internal state.

According to the seventh aspect described above, by including the degradation estimation portion that changes the search ranges of the plurality of parameters at the same timing, even when the number of parameters of an internal state of the secondary battery to be diagnosed increases, it is possible to prevent a decrease in an estimation accuracy of the internal state. For example, compared to the case where the search range of each parameter is not changed, it is possible to prevent an increase in variation (uncertainty) of an estimation result in association with an increase in the number of parameters.

According to the eighth or tenth aspect described above, by changing the search range at each different timing when acquiring the predetermined parameter, even when the number of parameters of an internal state of the secondary battery to be diagnosed increases, it is possible to prevent a decrease in an estimation accuracy of the internal state. For example, compared to the case where the search range is not changed, it is possible to prevent an increase in variation (uncertainty) of an estimation result in association with an increase in the number of parameters.

According to the ninth or eleventh aspect described above, by changing the search ranges of the plurality of parameters at the same timing, even when the number of parameters of an internal state of the secondary battery to be diagnosed increases, it is 5 possible to prevent a decrease in an estimation accuracy of the internal state. For example, compared to the case where the search range of each parameter is not changed, it is possible to prevent an increase in variation (uncertainty) of an estimation result in association with an increase in the number of parameters.

### BRIEF DESCRIPTION OF THE DRAWINGS

FIG. 1 is a block diagram showing a functional configuration of a system including a secondary battery state estimation device in an embodiment of the present invention.

FIG. 2 is a view showing an example of an OCV curve acquired based on an OCP curve of each of a positive electrode and a negative electrode by an optimization portion of the secondary battery state estimation device in the embodiment of the present invention.

FIG. 3 is a view showing an example of a flow of information in a parameter optimization process by the optimization portion of the secondary battery state estimation device in the embodiment of the present invention.

FIG. 4 is a view showing an example of a parameter in each of a positive electrode OCP curve and a negative electrode OCP curve set by the secondary battery state estimation device in the embodiment of the present invention.

FIG. 5 is a flowchart showing a process performed by the secondary battery state estimation device in the embodiment of the present invention.

FIG. 6 is a view showing an example of variation (uncertainty) of a parameter value obtained in each of the embodiment of the present invention and a comparative example.

### DESCRIPTION OF EMBODIMENTS

Hereinafter, a secondary battery state estimation system, a secondary battery state estimation method, and a program according to an embodiment of the present invention will be described with reference to the accompanying drawings.

A secondary battery according to an embodiment is, for example, detachably or fixedly arranged in various electric apparatuses.

Examples of various electric apparatuses include an electric vehicle, an electric movable body, an electric machine, an electric power source device, and the like. Examples of the electric vehicle include an electric automobile including a rotary electric machine driven by electric power of a secondary battery as a power source, a saddle riding vehicle, a kick skater, a hybrid vehicle by a combination of a rotary electric machine and an internal combustion engine, a fuel cell vehicle by a combination of a secondary battery and a fuel cell, and the like. Examples of the electric movable body include a robot, a movable work machine, a flying vehicle, a movable body on water, an underwater movable body, and the like. Examples of the electric machine include a construction machine including a rotary electric machine as a power source and the like. Examples of the electric power source device include a stationary or mobile electric power source device that performs discharging and charging of a secondary battery, an exchange device that supplies (provides) and receives a secondary battery for a user in a so-called battery share service, or the like.

Various electric apparatuses may include, for example, an external charging function of being charged by an external electric power source (an external DC electric power source and an external AC electric power source) such as a PHV (Plug-in Hybrid Vehicle) or a PHEV (Plug-in Hybrid Electric Vehicle). Various electric apparatuses may include, for example, a function of supplying electric power to the outside by the electric power of the secondary battery. Further, the rotary electric machine mounted on the electric vehicle may transfer electric power to and from the secondary battery, for example, by a regeneration operation using rotation power input from a wheel side, electric power generation by power input from an internal combustion engine, or the like in addition to a power running operation.

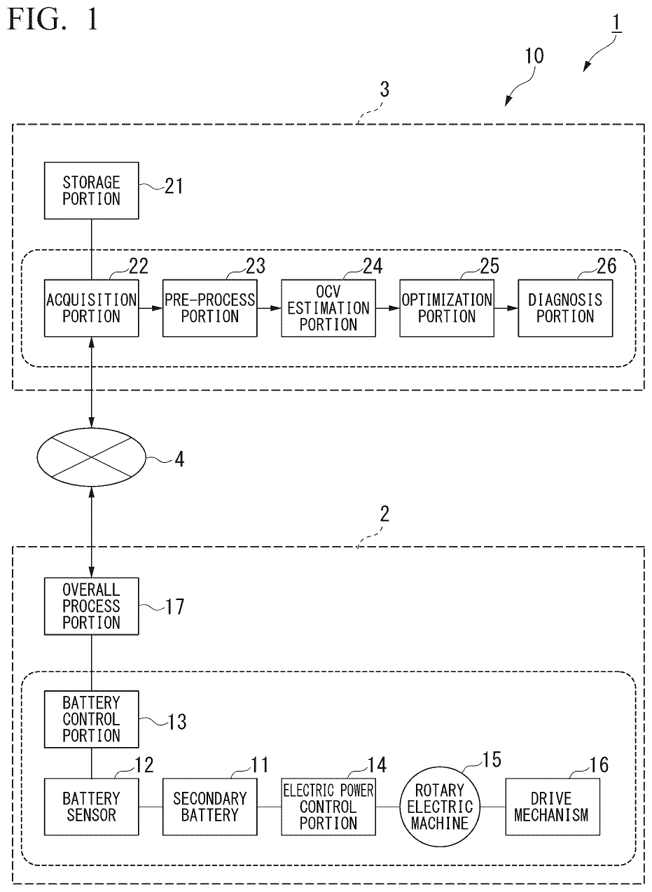

FIG. 1 is a block diagram showing a functional configuration of a system 1 including a secondary battery state estimation device 10 of the embodiment.

As shown in FIG. 1, a system 1 (a secondary battery state estimation system, an electronic apparatus) of the embodiment includes, for example, a vehicle 2 and a server 3. The vehicle 2 and the server 3 are connected to each other, for example, via a wired or wireless communication network (network) 4. Examples of the network 4 include the Internet, a mobile communication network, a LAN (Local Area Network), a WAN (Wide Area Network), and the like. The LAN is, for example, a wired LAN (Local Area Network) of a predetermined standard such as Ethernet or a wireless LAN of various standards such as Wi-Fi and Bluetooth (registered trademark).

The secondary battery state estimation device 10 of the embodiment is constituted, for example, of the server 3.

The vehicle 2 includes, for example, a secondary battery 11, a battery sensor 12, a battery control portion 13, an electric power control portion 14, a rotary electric machine 15, a drive mechanism 16, and an overall process portion 17.

The secondary battery 11 is, for example, a variety of batteries that repeat charging and discharging such as a lithium ion battery, a sodium ion battery, a nickel hydride battery, or the like. The electrolyte of the secondary battery 11 is, for example, a non-aqueous electrolyte such as a liquid, a solid, or a polymer.

A positive electrode active material that constitutes a positive electrode of the secondary battery 11 is, for example, a metal oxide containing lithium ions or the like in the case of a lithium ion battery.

The metal oxide containing lithium ions is, for example, a simple substance of a complex oxide by lithium and a metal such as nickel, cobalt, manganese, and aluminum, a mixture of a plurality of different complex oxides, or the like. The complex oxides are classified into a bedded salt type, a spinel type, and an olivine type, for example, from the viewpoint of a crystal structure. Examples of the complex oxides of the bedded salt type include lithium cobalt oxide (LCO: LiCoO₂), nickel-cobalt-manganese oxide (NCM: Li(NiₓCo_{y}Mn_{z})O₂), nickel-cobalt-aluminum oxide (NCA: LiNiₓCo_{y}AlₓO₂), and the like. Examples of the complex oxides of the spinel type include lithium manganese oxide (LMO: LiMn₂O₄), lithium nickel-manganese oxide (LNMO: LiNiₓMn_{y}O₄), and the like. Examples of the complex oxides of the olivine type include lithium iron phosphate (LFP: LiFePO₄), lithium manganese iron phosphate (LMFP: LiMnₓFe₍₁₋ₓ₎PO₄), and the like.

A negative electrode active material that constitutes a negative electrode of the secondary battery 11 is formed of, for example, a carbon material, an oxide material, a mixed material, or the like in the case of a lithium ion battery. Examples of the carbon material include graphite (black lead), hard carbon (non-graphitizable carbon), and the like. Examples of the oxide material include lithium titanate (LTO: Li₄Ti₅O₁₂) and the like. Examples of the mixed material include a mixed material of a metal material and a carbon material such as Si and Sn and the like, such as a mixed material of graphite and a silicon oxide (SiOₓ) or the like.

The battery sensor 12 includes, for example, various sensors that detect the state of the secondary battery 11. The battery sensor 12 includes, for example, a voltage sensor, a current sensor, a temperature sensor, and the like. The battery sensor 12 outputs, for example, signals of various detection values of the voltage, the current, the temperature, and the like relating to the state of the secondary battery 11.

The battery control portion 13 is, for example, a so-called BMU (Battery Management Unit) and monitors and controls the state of the secondary battery 11. The battery control portion 13 is, for example, a software function unit that functions by a predetermined program being executed by a processor such as a CPU (Central Processing Unit). The software function unit is an ECU (Electronic Control Unit) including a processor such as a CPU, a ROM (Read Only Memory) that stores a program, a RAM (Random Access Memory) that temporarily stores data, and an electronic circuit such as a timer. At least part of the battery control portion 13 may be an integrated circuit such as an LSI (Large Scale Integration).

The battery control portion 13 stores, for example, information relating to the secondary battery 11, a predetermined program, and the like. The information relating to the secondary battery 11 includes, for example, identification information such as an ID (Identifier) exclusively assigned to the secondary battery 11, the manufacturing date and time, the capacity of an initial state, information relating to the state of the secondary battery 11 based on an output of the battery sensor 12, and the like. The information relating to the state of the secondary battery 11 includes, for example, information relating to the current state such as a charging state such as a charging rate, a remaining capacity (SOC: State Of Charge), or an electric power amount, history of charging and discharging such as the number of times of charging, the voltage, and the temperature, information relating to the current degradation state such as the degree of degradation, information relating to the presence or absence of abnormality, and the like.

The electric power control portion 14 is connected to the secondary battery 11 and the rotary electric machine 15. The electric power control portion 14 includes, for example, a voltage converter such as a DC-DC converter that converts the voltage in DC and an electric power converter such as a DC-AC converter that converts electric power between DC and AC. The electric power control portion 14 controls electric power transfer between the secondary battery 11 and the rotary electric machine 15, for example, based on a control signal received from the overall process portion 17.

The rotary electric machine 15 is, for example, a three-phase AC brushless DC motor or the like. The rotary electric machine 15 generates rotation power by performing a power running operation by electric power that is supplied from the electric power control portion 14. For example, when the rotary electric machine 15 is connected to a wheel of the vehicle 2, the rotary electric machine 15 generates a travel drive force by performing the power running operation by the electric power that is supplied from the electric power control portion 14. The rotary electric machine 15 may generate electric power by performing a regeneration operation by rotation power that is input from the wheel side of the vehicle 2. When the rotary electric machine 15 is connected to an internal combustion engine of the vehicle 2, the rotary electric machine 15 may generate electric power by the power of the internal combustion engine.

The drive mechanism 16 is a power transmission mechanism connected to a rotor of the rotary electric machine 15. The drive mechanism 16 includes, for example, equipment elements such as a gear, a belt, and a chain. The drive mechanism 16 transmits, for example, power between the rotary electric machine 15 and the wheel of the vehicle 2. The drive mechanism 16 may include, for example, a regulation mechanism that regulates power transmission such as an electric parking brake that stops rotation of the wheel or a drive shaft and a parking lock mechanism.

The overall process portion 17 overall controls the operation of the vehicle 2. The overall process portion 17 includes, for example, a software function unit. At least part of the overall process portion 17 may include an integrated circuit.

The overall process portion 17 includes, for example, an input-output section and a communication section.

The input-output section includes, for example, various operation devices such as a keyboard, a touch panel, a mouse, and a button, a display device such as a liquid crystal display or an organic EL (Electro Luminescence) display, and various input-output devices such as a microphone for voice input and a speaker for sound output. The input-output section receives, for example, an operation by an operator such as a user or an input operation which is a voice input and outputs a signal in accordance with the input operation.

The communication section performs transmission and reception of various information to and from the server 3 via the network 4. The communication section transmits to the server 3, for example, information by a combination of information such as date and time, identification information of the vehicle 2 or the secondary battery 11, and information relating to the secondary battery 11 received from the battery control portion 13.

The server 3 includes, for example, a software function unit. At least part of the overall process portion 17 may include an integrated circuit. The server 3 includes, for example, a storage portion 21, an acquisition portion 22, a pre-process portion 23, an OCV estimation portion 24, an optimization portion 25 (degradation estimation portion, process portion), and a diagnosis portion 26.

The storage portion 21 stores, for example, various information such as information relating to the secondary battery 11 acquired by the server 3 in advance or received by the server 3 from the vehicle 2 at an appropriate timing and information generated by the server 3, and a predetermined program.

The acquisition portion 22 acquires, for example, time series data of the voltage, the current, the temperature, and the like of the secondary battery 11 from the vehicle 2. The voltage of the secondary battery 11 is, for example, the closed circuit voltage (CCV). The acquisition portion 22 acquires a discharge capacity (discharge amount), for example, by integrating the time series data of the current.

The pre-process portion 23 performs, for example, a process such as cleansing and filtering of the time series data acquired by the acquisition portion 22. The pre-process portion 23 excludes, for example, data in which a loss, an abnormality, or the like occurs from the time series data.

The OCV estimation portion 24 estimates the open circuit voltage (OCV, voltage data) of a secondary battery 11 to be estimated and acquires history data of the open circuit voltage (OCV) in the secondary battery 11 as described below.

The OCV estimation portion 24 extracts, for example, data in which a change caused by charging and discharging of the secondary battery 11 is equal to or less than a predetermined threshold value from the time series data processed by the pre-process portion 23. The OCV estimation portion 24 sets, for example, data indicating the change of the predetermined threshold value or less as data at a timing when the closed circuit voltage (CCV, voltage data) can be regarded as the open circuit voltage (OCV).

The OCV estimation portion 24 may estimate the open circuit voltage (OCV) of the secondary battery 11 to be estimated, for example, by using an appropriate machine learning model from the time series data processed by the pre-process portion 23. The OCV estimation portion 24 constructs a machine learning model that outputs the open circuit voltage (OCV) or voltage data relating to the open circuit voltage (OCV), for example, by using data acquired based on a test performed on the secondary battery 11 in which the degradation state is known, a simulation performed on a predetermined model of the secondary battery 11, or the like. The OCV estimation portion 24 inputs data of the current and the closed circuit voltage (CCV) at an appropriate timing detected in the secondary battery 11 to be estimated to the machine learning model and thereby acquires the open circuit voltage (OCV) at an arbitrary timing of the secondary battery 11 to be estimated.

The OCV estimation portion 24 may estimate the open circuit voltage (OCV) of the secondary battery 11 to be estimated, for example, by using an appropriate equivalent circuit model.

The OCV estimation portion 24 stores the acquired open circuit voltage (OCV) at an arbitrary timing (date and time or the like) in the storage portion 21 as history data of the open circuit voltage (OCV).

The history data is, for example, data acquired in an appropriate period and is not limited to a series of data such as the time series data.

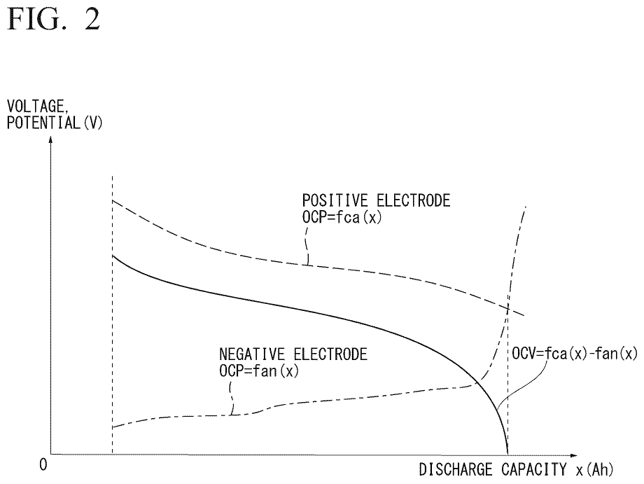

FIG. 2 is a view showing an example of an OCV curve acquired based on an OCP curve of each of a positive electrode and a negative electrode by the optimization portion 25 of the secondary battery state estimation device 10 in the embodiment.

As shown in FIG. 2, the optimization portion 25 acquires an OCP curve indicating a change in an open circuit potential (OCP) in accordance with a discharge capacity x (Ah) of each of the positive electrode and the negative electrode of the secondary battery 11, for example, based on a plurality of parameters relating to the state of the secondary battery 11. The optimization portion 25 acquires a positive electrode OCP curve (=fca (x)) and a negative electrode OCP curve (=fan (x)), for example, by causing a plurality of parameters to act on an OCP curve (reference OCP curve) stored in advance in the storage portion 21.

The reference OCP curve stored in the storage portion 21 is acquired, for example, by a test performed in advance, a simulation by an appropriate model, or the like. The reference OCP curve is, for example, an OCP curve of a simple substance of each active material constituting each of the positive electrode and the negative electrode of the secondary battery 11. The optimization portion 25 estimates the OCV curve (=fca (x)−fan (x)) indicating the change in the open circuit voltage (OCV) in accordance with the discharge capacity x (Ah), for example, based on the difference between the positive electrode OCP curve (=fca (x)) and the negative electrode OCP curve (=fan (x)).

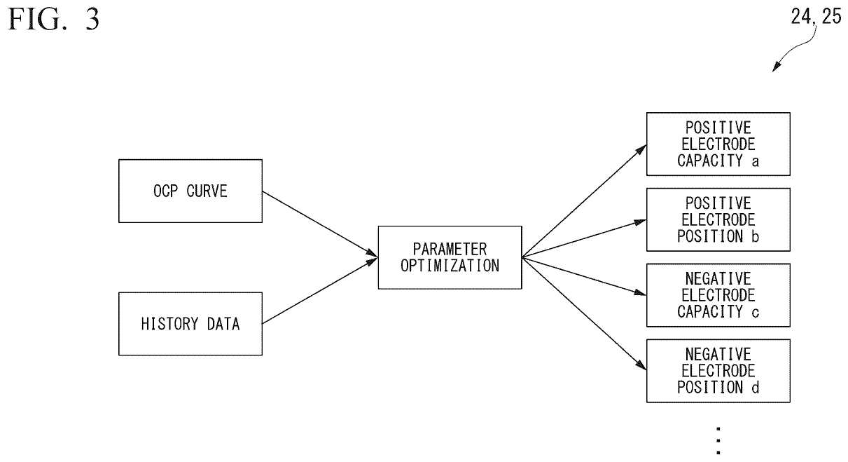

FIG. 3 is a view showing an example of a flow of information in a parameter optimization process by the optimization portion 25 of the secondary battery state estimation device 10 in the embodiment.

As shown in FIG. 3, the plurality of parameters relating to the state of the secondary battery 11 include, for example, a positive electrode capacity a, a positive electrode position b, a negative electrode capacity c, a negative electrode position d, and the like. A parameter optimization process performed by the optimization portion 25 includes, for example, generation of an OCV curve based on the positive electrode OCP curve (=fca (x)) and the negative electrode OCP curve (=fan (x)) and optimization (reconfiguring) of the plurality of parameters. The optimization portion 25 optimizes the plurality of parameters relating to the state of the secondary battery 11, for example, based on the OCV curve estimated based the OCP curve and the history data of the secondary battery 11.

The optimization portion 25 performs, for example, a predetermined optimization process based on an error function indicating an error between the OCV curve acquired based on the OCP curve of each of the positive electrode and the negative electrode and the history data of the open circuit voltage (OCV) of the secondary battery 11. The error function is, for example, a weighted mean square error (Weighted RMSE), a weighted mean absolute error (Weighted MAE), or the like. The predetermined optimization process is, for example, a local optimization algorithm such as a BFGS method, a conjugate gradient method, and a COBYLA method, a global optimization algorithm such as a genetic algorithm, a differential evolution method, a SHGO method, and an annealing method, or the like. In the parameter optimization process, for example, reconfiguring of the plurality of parameters by the optimization portion 25, acquisition of the positive electrode OCP curve and the negative electrode OCP curve, and estimation of the OCV curve are repeated so that the value of the error function becomes equal to or less than a predetermined value.

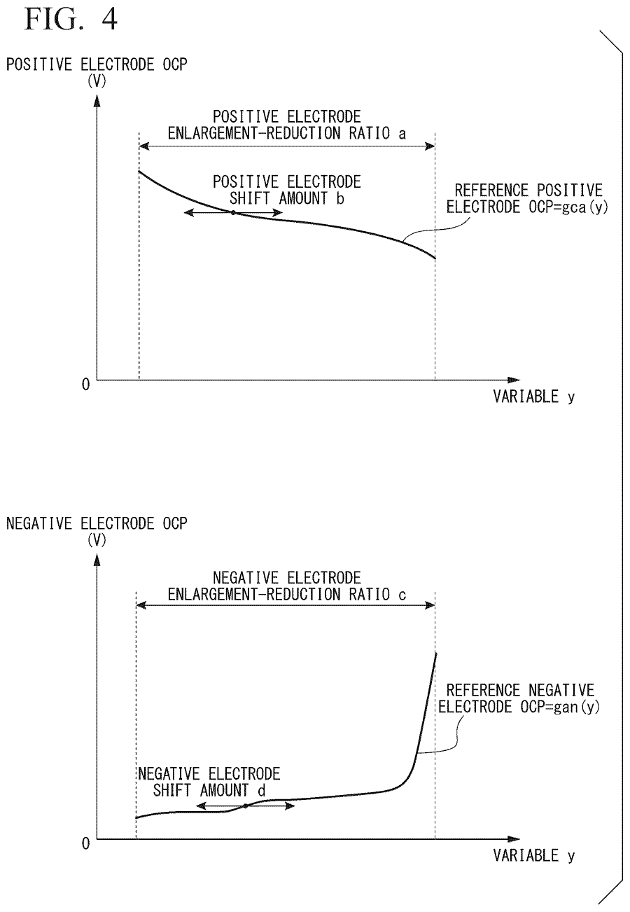

FIG. 4 is a view showing an example of a parameter in each of a positive electrode OCP curve and a negative electrode OCP curve set by the secondary battery state estimation device 10 in the embodiment.

The parameter shown in FIG. 4 generates a positive electrode OCP curve (=fca (x)) and a negative electrode OCP curve (=fan (x)) which are mathematical models in which a discharge capacity x (Ah) is a variable, for example, by acting on a reference positive electrode OCP curve (=gca (y)) and a reference negative electrode OCP curve (=gan (y)) which are predetermined mathematical models by a dimensionless variable y. Each of the reference positive electrode OCP curve and the reference negative electrode OCP curve shown in FIG. 4 is a composite OCP curve obtained by an OCP curve of a simple substance of each active material, for example, in the case of an electrode constituted by a mixing of a plurality of active materials such as a mixed material.

The parameters shown in FIG. 4 are, for example, a positive electrode capacity a and a positive electrode position b that convert the reference positive electrode OCP curve into a positive electrode OCP curve, and a negative electrode capacity c and a negative electrode position d that convert the reference negative electrode OCP curve into a negative electrode OCP curve.

The positive electrode capacity a and the positive electrode position b are, for example, a positive electrode enlargement-reduction ratio a relating to the size of a width of the discharge capacity and a positive electrode shift amount b relating to the position in a discharge capacity direction and convert a dimensionless variable y into a discharge capacity x (=a×y+b). The negative electrode capacity c and the negative electrode position d are, for example, a negative electrode enlargement-reduction ratio c relating to the size of a width of the discharge capacity and a negative electrode shift amount d relating to the position in the discharge capacity direction and convert the dimensionless variable y into the discharge capacity x (=c×y+d).

When performing the predetermined optimization process, for example, the optimization portion 25 classifies a plurality of parameters into a plurality of groups having a different search condition. The plurality of groups include, for example, a first group in which a search range is not limited, a second group in which a search range is limited, and the like. For example, the search range set with respect to a parameter of the first group is an entire region as a target and is all within the range set by a predetermined lower limit value and a predetermined upper limit value. For example, the search range set with respect to a parameter of the second group is a limited region in the entire region as a target and is within a range set by a predetermined limitation value and a reference value based on a past estimation value. The reference value based on the past estimation value is, for example, an average value or a median value of past estimation values, a last-minute estimation value, a prediction value predicted by a regression model or the like from a past estimation value, or the like. The predetermined limitation value is, for example, a value that changes in accordance with a past estimation value or the like, a fixed value, or the like.

For example, with respect to an appropriate parameter p, when a predetermined lower limit value pmin, a predetermined upper limit value pmax, a reference value p0 based on a past estimation value, and a predetermined limitation value pr are set, the search range when the parameter p is classified into the first group is pmin≤p≤pmax. Further, the search range when the parameter p is classified into the second group is, for example, p0−pr≤p≤p0+pr.

When classifying the plurality of parameters into the plurality of groups having a different search condition, for example, the optimization portion 25 sets the grouping in accordance with the type of a degradation state or a degradation mechanism of the secondary battery 11 to which each parameter relates or the like. The type of the degradation state or the degradation mechanism of the secondary battery 11 is, for example, degradation of a positive electrode capacity, degradation of a negative electrode capacity, a loss amount of ion that plays a role in electrical conduction, or the like. For example, the positive electrode enlargement-reduction ratio a relates to the degradation of the positive electrode capacity, the negative electrode enlargement-reduction ratio c relates to the degradation of the negative electrode capacity, and the positive electrode shift amount b and the negative electrode shift amount d relate to the loss amount of ion.

Table 1 described below shows an example in which, for example, in each of the predetermined optimization processes performed a plurality of times, the positive electrode enlargement-reduction ratio a, the positive electrode shift amount b, the negative electrode enlargement-reduction ratio c, and the negative electrode shift amount d are classified into the parameter of the first group and the parameter of the second group.

As shown in Table 1 described below, the optimization portion 25 classifies, for example, each of the positive electrode enlargement-reduction ratio a and the negative electrode enlargement-reduction ratio c that relate to different types of degradation states from each other into a group independently of each other. The optimization portion 25 combines, for example, the positive electrode shift amount b and the negative electrode shift amount d that relate to the same type of the degradation state as each other and classifies the positive electrode shift amount b and the negative electrode shift amount d into an identical group.

TABLE 1

| | FIRST | SECOND | THIRD | FOURTH | FIFTH | |
|---|---|---|---|---|---|---|
| | TIME | TIME | TIME | TIME | TIME | . . . |
| FIRST GROUP | a | b, d | c | a | b, d | . . . |
| PARAMETER | | | | | | |
| SECOND GROUP | b, c, d | a, c | a, b, d | b, c, d | a, c | . . . |
| PARAMETER | | | | | | |

As shown in Table 1 described above, the optimization portion 25 changes the classification (grouping) of the plurality of parameters, for example, at each predetermined optimization process that is repeatedly performed. The optimization portion 25 differentiates a search range when acquiring a predetermined parameter among the plurality of parameters at an appropriate first time and a search range when acquiring the predetermined parameter at an appropriate second time that is different from the first time, for example, by the change of classification. In an example of Table 1 described above, the optimization portion 25 changes the classification of the plurality of parameters by predetermined cyclic setting.

The change of classification is not limited to the predetermined cyclic change as shown in Table 1 described above, and the optimization portion 25 may change the classification of the plurality of parameters, for example, by predetermined regular setting based on the design characteristic, the degradation mechanism, the tendency of degradation, and the like of the secondary battery 11. For example, when there is a feature in which the positive electrode capacity of the secondary battery 11 easily decreases selectively, the optimization portion 25 may set a frequency of classifying the positive electrode enlargement-reduction ratio a into the parameter of the first group to be relatively large. For example, when there is a feature in which a capacity reduction speed at a degradation initial stage of the secondary battery 11 is relatively large, and a capacity reduction speed at a degradation end stage is relatively small, the optimization portion 25 may change a frequency of classifying the positive electrode enlargement-reduction ratio a and the negative electrode enlargement-reduction ratio c into the parameter of the first group in a decreasing trend from the degradation initial stage toward the degradation end stage.

The diagnosis portion 26 acquires a diagnosis value relating to the degradation state of the secondary battery 11, for example, based on the OCV curve estimated based on the OCP curve after the optimization of the plurality of parameters by the optimization portion 25. The diagnosis portion 26 sets the ratio of a full charge capacity at the time of degradation as a SOH (State of Health) diagnosis value, for example, assuming that the full charge capacity in the initial state of the secondary battery 11 is 100%. The full charge capacity at the time of degradation is, for example, a difference between a discharge capacity at a full discharge voltage and a discharge capacity at a full charge voltage acquired based on the OCV curve.

The diagnosis portion 26 associates, for example, an acquired SOH diagnosis value with the date and time when the OCV curve is obtained by the optimization portion 25 and thereby stores history data of the SOH diagnosis value in the storage portion 21.

### (Operation of Secondary Battery State Estimation Device)

Hereinafter, an operation of the secondary battery state estimation device 10 of the embodiment, particularly a process performed by the optimization portion 25 is described.

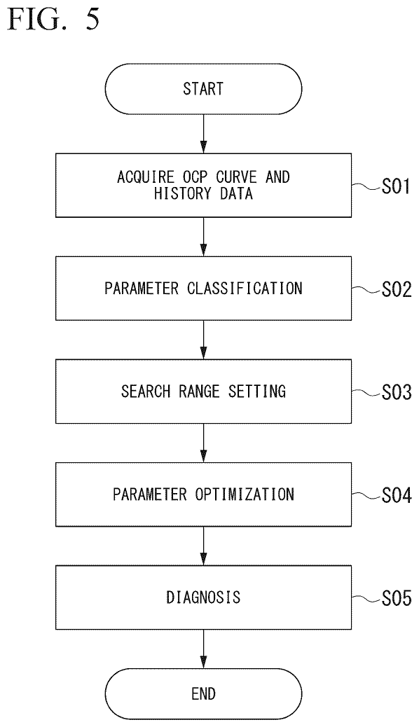

FIG. 5 is a flowchart showing a process performed by the secondary battery state estimation device 10 in the embodiment. A series of processes from Step S01 to Step S05 shown in FIG. 5 are repeatedly performed at an appropriate timing.

As shown in FIG. 5, first, the optimization portion 25 acquires, for example, an OCP curve (reference OCP curve) of a simple substance of each active material constituting each of the positive electrode and the negative electrode of the secondary battery 11. The optimization portion 25 acquires, for example, a positive electrode OCP curve (=fca (x)) and a negative electrode OCP curve (=fan (x)) based on the reference OCP curve and the plurality of parameters. The optimization portion 25 estimates an OCV curve (=fca (x)−fan (x)), for example, based on the difference between the positive electrode OCP curve (=fca (x)) and the negative electrode OCP curve (=fan (x)). The optimization portion 25 acquires, for example, history data of the secondary battery 11 (Step S01).

Next, the optimization portion 25 classifies, for example, the plurality of parameters into a plurality of groups having a different search condition. The optimization portion 25 sets, for example, classification (grouping) that is different from the previous process with respect to the plurality of parameters (Step S02).

Next, the optimization portion 25 sets a search range of each parameter, for example, in accordance with the search condition set for each of the plurality of groups (Step S03).

Next, the optimization portion 25 searches and optimizes each parameter in accordance with the search range of each of the plurality of parameters by a predetermined optimization process, for example, based on the estimated OCV curve and the history data of the secondary battery 11 (Step S04). Then, the optimization portion 25 advances the process to Step S05.

Next, the diagnosis portion 26 acquires a diagnosis value relating to the degradation state of the secondary battery 11, for example, based on the OCV curve estimated after the optimization of the plurality of parameters by the optimization portion 25 (Step S05). Then, the diagnosis portion 26 advances the process to the end.

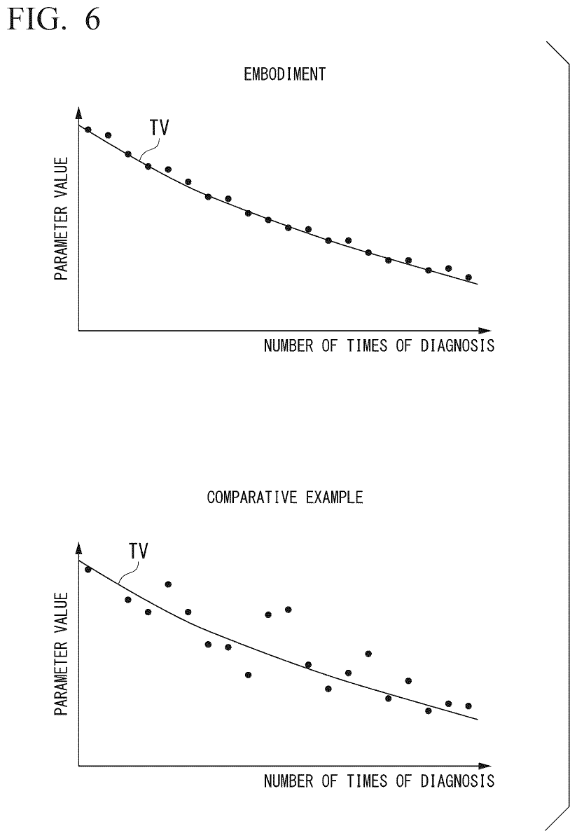

FIG. 6 is a view showing an example of variation (uncertainty) of a parameter value obtained in each of the embodiment and a comparative example. The comparative example corresponds to, for example, the case where classification of the plurality of parameters into the plurality of groups by the optimization portion 25 is not performed in the embodiment described above, that is, the case where the search conditions of the plurality of parameters are set to be identical to each other.

As shown in FIG. 6, for example, it is recognized that with respect to a true value TV of an appropriate parameter that changes in a decreasing trend in association with an increase in the number of times of diagnosis, variation (uncertainty) of a parameter value obtained in the embodiment is further decreased compared to that of a parameter value obtained in the comparative example.

As described above, according to the system 1 including the secondary battery state estimation device 10 of the embodiment, by including the optimization portion 25 that classifies the plurality of parameters into the plurality of groups having a different search condition at each predetermined optimization process that is repeatedly performed, it is possible to prevent a decrease in an estimation accuracy of an internal state of the secondary battery 11. The optimization portion 25 changes the classification of the plurality of parameters at each predetermined optimization process, and thereby, for example, compared to the case where the search condition is not changed, it is possible to prevent an increase in variation (uncertainty) of an estimation result in association with an increase in the number of parameters.

The optimization portion 25 classifies the plurality of parameters into the first group in which the search range is not limited and the second group in which the search range is limited, and thereby, for example, compared to the case where the search ranges of all of the parameters are not limited, it is possible to prevent the increase in variation (uncertainty) of the estimation result in association with the increase in the number of parameters.

The optimization portion 25 sets the grouping in accordance with the type of the degradation state or the degradation mechanism of the secondary battery 11 to which each parameter relates or the like and thereby can improve the estimation accuracy of each parameter.

### Modification Example

Hereinafter, modification examples of the embodiment is described. The same parts as those in the embodiment described above are denoted by the same reference numerals, and descriptions thereof are omitted or simplified.

The above embodiment is described using an example in which the secondary battery state estimation device 10 is constituted of the server 3; however, the embodiment is not limited thereto. For example, at least one of the processes performed by the server 3 may be performed by the battery control portion 13 of the vehicle 2. That is, the secondary battery state estimation device 10 may be constituted of the server 3 and the battery control portion 13 or only of the battery control portion 13.

The above embodiment is described using an example in which the plurality of groups having a different search condition are set to the first group in which the search range is not limited and the second group in which the search range is limited; however, the embodiment is not limited thereto.

For example, the search condition may be the size of a width of the search range. For example, the plurality of groups may be set to a first group in which the width of the search range is relatively large, a second group in which the width of the search range is relatively small, and the like.

The above embodiment is described using an example in which the plurality of parameters are classified into a plurality of groups in which a different search condition from each other is set in advance; however, the embodiment is not limited thereto. For example, after the plurality of parameters may be classified into a plurality of different groups in a state where a search condition is not set in advance, and a different search condition from each other may be set in the plurality of groups.

For example, the optimization portion 25 may set the width of the search range when acquiring the parameter of the first group at an appropriate first time to be larger than the width of the search range when acquiring the parameter of the second group at the first time. For example, the optimization portion 25 may set the width of the search range when acquiring the parameter of the first group at an appropriate second time that is different from the first time to be smaller than the width of the search range when acquiring the parameter of the second group at the second time.

The above embodiment is described using an example in which the optimization portion 25 changes the classification of the plurality of parameters by predetermined regular setting; however, the embodiment is not limited thereto. For example, the optimization portion 25 may change the classification of the plurality of parameters by random selection. For example, the above embodiment is described using an example in which the optimization portion 25 combines the positive electrode shift amount b and the negative electrode shift amount d that relate to the same type of the degradation state as each other and classifies the positive electrode shift amount b and the negative electrode shift amount d into an identical group; however, the embodiment is not limited thereto. The optimization portion 25 may classify the positive electrode shift amount b and the negative electrode shift amount d that relate to the same type of the degradation state as each other into a group independently of each other.

The above embodiment is described using an example in which the plurality of parameters include the positive electrode capacity a, the positive electrode position b, the negative electrode capacity c, and the negative electrode position d; however, the present invention is not limited thereto. For example, the plurality of parameters may include another parameter such as an active material capacity ratio and a voltage correction parameter. For example, the active material capacity ratio is a ratio set by a capacity of each active material with respect to an electrode constituted by a mixing of a plurality of active materials such as a mixed material. For example, the voltage correction parameter is a parameter that corrects the shape of the OCP curve or the OCV curve or the like.

In the embodiment described above, the positive electrode position b or the negative electrode position d among the plurality of parameters may be, for example, a relative position of the negative electrode OCP curve relative to the positive electrode OCP curve, a relative position of the positive electrode OCP curve relative to the negative electrode OCP curve, or the like.

The above embodiment is described using an example in which the OCP curve and the OCV curve are changes of the open circuit potential (OCP) or the open circuit voltage (OCV) in accordance with the discharge capacity x (Ah); however, the embodiment is not limited thereto. For example, a parameter relating to the capacity such as a charge capacity (Ah), a remaining capacity (SOC: State of Charge), or a depth of discharge (DOD: Depth of Discharge) may be used instead of the discharge capacity (Ah). The change tendency of the open circuit potential (OCP) or the open circuit voltage (OCV) is reversed between the discharge capacity (Ah) and the charge capacity (Ah).

For example, a capacity region having a predetermined discharge capacity or more corresponds to a capacity region having a predetermined charge capacity or less. A program for realizing all or some of the functions of the system 1 including the secondary battery state estimation device 10 in the present invention may be recorded in a computer-readable recording medium, the program recorded in the recording medium may be read into and executed by a computer system, and thereby, all or some of the processes performed by the system 1 may be performed. It is assumed that the term “computer system” used herein includes an OS or hardware such as peripherals. Further, it is also assumed that the term “computer system” includes a WWW system which includes a homepage-providing environment (or a display environment). Further, the term “computer-readable recording medium” refers to a portable medium such as a flexible disk, a magneto-optical disk, a ROM, and a CD-ROM and a storage device such as a hard disk embedded in the computer system. Further, it is also assumed that the term “computer-readable recording medium” includes a medium which holds a program for a given time such as a volatile memory (RAM) in the computer system which becomes a server or a client when a program is transmitted through a network such as the Internet or a communication line such as a telephone line.

Further, the program may be transmitted from the computer system which stores the program in the storage device or the like to another computer system through a transmission medium or through transmission waves in the transmission medium. Here, the term “transmission medium” which transmits the program refers to a medium having a function of transmitting information that is, for example, a network (communication network) such as the Internet or a communication line such as a telephone line. Further, the program may be a program for realizing some of the above-described functions. Further, the program may be a so-called differential file (differential program) which can realize the above-described functions by a combination with a program already recorded in the computer system.

These embodiments of the present invention have been presented as examples and are not intended to limit the scope of the invention. These embodiments can be implemented in a variety of other modes, and various omissions, substitutions, and changes can be made without departing from the scope of the invention. These embodiments and modifications thereof are included in the scope and gist of the invention and are also included in the scope of the invention described in the appended claims and equivalent thereof.

What is claimed is:

1. A secondary battery state estimation system comprising:
a degradation estimation portion that acquires a plurality of parameters relating to a state of a secondary battery to be estimated based on voltage data which is acquired in the secondary battery to be estimated or which is acquired by data acquired in a secondary battery and thereby estimates a degradation degree of the secondary battery to be estimated,
wherein the degradation estimation portion differentiates a search range when acquiring a predetermined parameter among the plurality of parameters at a first time and a search range when acquiring the predetermined parameter at a second time that is different from the first time.

2. The secondary battery state estimation system according to claim 1,
wherein the degradation estimation portion differentiates
a search range when acquiring a first parameter which is the predetermined parameter among the plurality of parameters at a predetermined time and
a search range when acquiring a second parameter that is different from the first parameter among the plurality of parameters at the predetermined time.

3. The secondary battery state estimation system according to claim 2,
wherein the degradation estimation portion
sets a search range when acquiring the first parameter at the first time to be larger than a search range when acquiring the second parameter at the first time and
sets a search range when acquiring the first parameter at the second time to be smaller than a search range when acquiring the second parameter at the second time.

4. The secondary battery state estimation system according to claim 1,
wherein the degradation estimation portion
sets a first group and a second group which have a search range different from each other and in each of which at least one parameter is classified from the plurality of parameters and
changes classification in which the plurality of parameters are classified into the first group and the second group at each different time.

5. The secondary battery state estimation system according to claim 1,
wherein the degradation estimation portion
classifies the plurality of parameters into a first group having at least one parameter and a second group having at least one parameter and
differentiates a search range when acquiring a parameter of the first group at a predetermined time and a search range when acquiring a parameter of the second group at the predetermined time.

6. The secondary battery state estimation system according to claim 5,
wherein the degradation estimation portion
sets a search range when acquiring a parameter of the first group at the first time to be larger than a search range when acquiring a parameter of the second group at the first time and
sets a search range when acquiring a parameter of the first group at the second time to be smaller than a search range when acquiring a parameter of the second group at the second time.

7. A secondary battery state estimation system comprising:
a degradation estimation portion that acquires a plurality of parameters relating to a state of a secondary battery to be estimated based on voltage data which is acquired in the secondary battery to be estimated or which is acquired by data acquired in a secondary battery and thereby estimates a degradation degree of the secondary battery to be estimated,
wherein the degradation estimation portion differentiates a search range when acquiring a first parameter among the plurality of parameters at a predetermined time and a search range when acquiring a second parameter that is different from the first parameter among the plurality of parameters at the predetermined time.

8. A secondary battery state estimation method performed by an electronic apparatus including a process portion that estimates a degradation degree of a secondary battery to be estimated, the method including:
acquiring a plurality of parameters relating to a state of the secondary battery to be estimated based on voltage data which is acquired in the secondary battery to be estimated or which is acquired by data acquired in a secondary battery; and
differentiating a search range when acquiring a predetermined parameter among the plurality of parameters at a first time and a search range when acquiring the predetermined parameter at a second time that is different from the first time.

9. A secondary battery state estimation method performed by an electronic apparatus including a process portion that estimates a degradation degree of a secondary battery to be estimated, the method including:
acquiring a plurality of parameters relating to a state of the secondary battery to be estimated based on voltage data which is acquired in the secondary battery to be estimated or which is acquired by data acquired in a secondary battery; and
differentiating a search range when acquiring a first parameter among the plurality of parameters at a predetermined time and a search range when acquiring a second parameter that is different from the first parameter among the plurality of parameters at the predetermined time.

10. A computer-readable non-transitory recording medium that records a program causing a computer of an electronic apparatus including a process portion that estimates a degradation degree of a secondary battery to be estimated to execute:
acquiring a plurality of parameters relating to a state of the secondary battery to be estimated based on voltage data which is acquired in the secondary battery to be estimated or which is acquired by data acquired in a secondary battery; and
differentiating a search range when acquiring a predetermined parameter among the plurality of parameters at a first time and a search range when acquiring the predetermined parameter at a second time that is different from the first time.

11. A computer-readable non-transitory recording medium that records a program causing a computer of an electronic apparatus including a process portion that estimates a degradation degree of a secondary battery to be estimated to execute:
acquiring a plurality of parameters relating to a state of the secondary battery to be estimated based on voltage data which is acquired in the secondary battery to be estimated or which is acquired by data acquired in a secondary battery; and
differentiating a search range when acquiring a first parameter among the plurality of parameters at a predetermined time and a search range when acquiring a second parameter that is different from the first parameter among the plurality of parameters at the predetermined time.
